(19) United States
(12) Patent Application Publication
(10) Pub. No.: US 2025/0223700 A1
(43) Pub. Date: Jul. 10, 2025

(54) COOLING DEVICE, SUBSTRATE PROCESSING APPARATUS, AND COOLING METHOD

(71) Applicant: Tokyo Electron Limited, Tokyo (JP)

(72) Inventor: Kyoko IKEDA, Nirasaki City (JP)

(21) Appl. No.: 19/090,806

(22) Filed: Mar. 26, 2025

Related U.S. Application Data
(63) Continuation of application No. PCT/JP2023/031593, filed on Aug. 30, 2023.

(30) Foreign Application Priority Data
Sep. 30, 2022 (JP) 2022-157411

(51) Int. Cl. C23C 16/455; C23C 16/06

(52) U.S. Cl. CPC C23C 16/45572; C23C 16/06; C23C 16/45565

(57) ABSTRACT

A cooling device that cools a cooling target using a gas, includes: a housing configured to accommodate the cooling target and having a sidewall surrounding the cooling target; a plurality of supply holes arranged at an interval in the sidewall of the housing and serving as a flow path to introduce the gas from an external space of the housing to an interior of the housing; and a discharge path opened to the housing and configured to discharge the gas in the interior of the housing, wherein, to form a swirling flow rotating along the sidewall in the interior of the housing, each of the plurality of supply holes is formed toward a direction in which the gas is released along the swirling flow, when the housing is viewed in a plan view.

### CROSS-REFERENCE TO RELATED APPLICATION

This application is a Bypass Continuation application of PCT International Application No. PCT/JP2023/031593, filed on Aug. 30, 2023 and designating the United States, the international application being based upon and claiming the benefit of priority from Japanese Patent Application No. 2022-157411, filed on Sep. 30, 2022, the entire contents of which are incorporated herein by reference.

### TECHNICAL FIELD

The present disclosure relates to a cooling device, a substrate processing apparatus, and a cooling method.

### BACKGROUND

In a manufacturing process of semiconductor devices, for example, process gases and reactant gases are supplied to a shower head, and are released in a dispersed manner into a processing container that has been adjusted to a vacuum state, thereby performing a film formation process on a semiconductor wafer (hereinafter, referred to as “wafer”), which serves as a substrate. Patent Document 1 describes a technique in which a dry air supply pipe is provided to discharge dry air toward a support portion of the shower head heated for ensuring uniform processing, in order to cool the support portion and the surroundings of the support portion.

### PRIOR ART DOCUMENTS

### Patent Documents

Patent Document 1: Japanese Patent Laid-Open Publication No. 2008-214763

### SUMMARY

According to one embodiment of the present disclosure, there is provided a cooling device that cools a cooling target using a gas, including: a housing configured to accommodate the cooling target and having a sidewall surrounding the cooling target; a plurality of supply holes arranged at an interval in the sidewall of the housing and serving as a flow path to introduce the gas from an external space of the housing to an interior of the housing; and a discharge path opened to the housing and configured to discharge the gas in the interior of the housing, wherein, to form a swirling flow rotating along the sidewall in the interior of the housing, each of the plurality of supply holes is formed toward a direction in which the gas is released along the swirling flow, when the housing is viewed in a plan view.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view illustrating a film forming apparatus according to a first embodiment of the present disclosure.

FIG. 2 is a perspective view illustrating a cooling device according to the first embodiment.

FIG. 3 is a cross-sectional plan view of the cooling device according to the first embodiment.

FIG. 4 is a cross-sectional plan view illustrating an operation of the cooling device according to the first embodiment.

FIG. 5 is a cross-sectional plan view illustrating an operation of the cooling device according to the first embodiment.

FIG. 6 is a longitudinal cross-sectional side view illustrating an operation of the cooling device according to the first embodiment.

FIG. 7 is a cross-sectional plan view illustrating an operation of a cooling device according to a comparative embodiment.

FIG. 8 is a longitudinal cross-sectional side view illustrating an operation of the cooling device according to the comparative embodiment.

FIG. 9 is a perspective view illustrating a cooling device according to a second embodiment of the present disclosure.

FIG. 10 is a perspective view illustrating a cooling device according to the second embodiment of the present disclosure.

FIG. 11 is a cross-sectional plan view illustrating a cooling device according to a third embodiment of the present disclosure.

FIG. 12 is a cross-sectional plan view illustrating a cooling device according to a fourth embodiment of the present disclosure.

FIG. 13 is an image illustrating simulation results in Example 1.

FIG. 14 is an image illustrating simulation results in Example 2.

FIG. 15 is an image illustrating simulation results in Comparative Example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

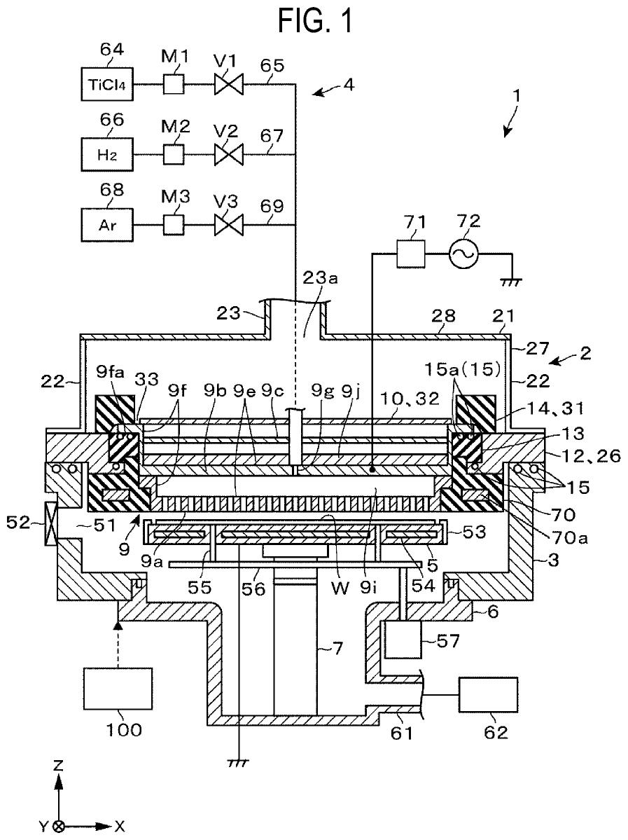

Hereinafter, as a first embodiment of a substrate processing apparatus according to the present disclosure, a film forming apparatus 1 for forming a titanium (Ti) thin film on a semiconductor wafer W (hereinafter referred to as “substrate W”) using a chemical vapor deposition (CVD) method will be described with reference to FIG. 1.

FIG. 1 is a longitudinal cross-sectional side view illustrating the film forming apparatus 1 according to this example. The film forming apparatus 1 includes a substantially cylindrical processing container 3 having an airtight configuration, a shower head 9 installed at the top of the processing container 3, a gas supply mechanism 4 for supplying film formation gases into the processing container 3 through the shower head 9, and a controller 100.

The processing container 3 includes, in a sidewall of the processing container 3, a loading/unloading port 51 for loading or unloading the substrate W and a gate valve 52 for opening or closing the loading/unloading port 51. A substrate stage 5 for horizontally placing the substrate W to be processed is installed inside the processing container 3. A stage holder 6 having a downwardly protruding cup shape is installed on a bottom center of the processing container 3 via a seal ring. The substrate stage 5 may hold a cylindrical support 7, which is in turn attached to the stage holder 6. Both the processing container 3 and the stage holder 6 include a heating mechanism (not illustrated) and are heated to a preset temperature upon receiving power supplied from a power supply (not illustrated).

A ring 53 is installed on an outer edge of an upper surface and a side surface of the substrate stage 5 to stabilize plasma generation. Further, a substrate heater 54 is embedded within the substrate stage 5. The substrate heater 54 heats the substrate W to a preset temperature upon receiving power supplied from a power supply (not illustrated). Further, the substrate stage 5 also functions as a lower electrode, with respect to an upper electrode to be described later, and is grounded.

The substrate stage 5 is installed with three (only two are illustrated) substrate support pins 55 for supporting and lifting the substrate W. These substrate support pins 55 are installed to be capable of protruding or retracting relative to the surface of the substrate stage 5 and are fixed to a support plate 56. The substrate support pins 55 are then raised or lowered by a drive mechanism 57, such as an air cylinder, via the support plate 56.

An exhaust pipe 61 is connected to a bottom sidewall of the stage holder 6, and an exhaust device 62 is connected to the exhaust pipe 61 to evacuate the processing container 3. Then, by operating the exhaust device 62, an interior of the processing container 3 may be depressurized to a preset vacuum level.

The shower head 9 is arranged to face the substrate stage 5. The shower head 9 includes a lower plate 9a, a middle plate 9b, and an upper plate 9c, each of which has a circular planar shape. The lower plate 9a and middle plate 9b each include a horizontal portion 9e, which is formed in a recessed shape and forms a shower head main body, and an annular support portion 9f, which is provided at the outer peripheral region of the horizontal portion 9e and is formed to protrude upward.

A plurality of through-holes are formed radially and evenly in the lower surface of the horizontal portion 9e of the lower plate 9a. An upper surface of the support portion 9f of the lower plate 9a is airtightly joined to a lower surface of the horizontal portion 9e of the middle plate 9b. A gas diffusion space 9i is defined inside the lower plate 9a, which is blocked by the lower surface of the horizontal portion 9e of the middle plate 9b. A gas introduction hole 9g is formed in the horizontal portion 9e of the middle plate 9b, and the gas supply mechanism 4 is connected to the gas introduction hole 9g. With this configuration, film formation gases entering the gas diffusion space 9i are released into the processing container 3 via the plurality of through-holes in the horizontal portion 9e of the lower plate 9a.

Further, the horizontal portion 9e of the middle plate 9b is connected to a radio frequency power supply 72 via a matcher 71, and functions as an upper electrode facing the aforementioned lower electrode (substrate stage 5). Thus, when radio frequency power is supplied from the radio frequency power supply 72 to the shower head 9, an electric field is formed between the shower head 9 and the substrate stage 5 to cause the film formation gases supplied into the processing container 3 to be plasmarized, resulting in acquisition of active species that promote a film formation reaction.

The middle plate 9b includes a first heater 9j disposed on the horizontal portion 9e. A target temperature of the shower head 9 may be set, for example, to approximately 500 degrees C., in order to prevent the deposition of by-products. The upper plate 9c is positioned inside a recess of the middle plate 9b to cover an upper side of the first heater 9j. The upper plate 9c contains, for example, aluminum (Al) and serves to prevent a leakage of radio frequency power for plasma generation.

The support portion 9f of the middle plate 9b has an outwardly protruding flange 9fa, and a disk-shaped lid 10 is installed on an upper surface of an inner portion of the flange 9fa to cover the entire recess of the middle plate 9b. A space is interposed between the lid 10 and the upper plate 9c. The lid 10 contains, for example, aluminum, similar to the upper plate 9c. A flow path, which is downstream of the gas supply mechanism 4, is connected to the center of the middle plate 9b so as to penetrate the lid 10, the upper plate 9c, and the first heater 9j.

When forming a titanium thin film as described above, for example, the gas supply mechanism 4 includes a TiCl₄ gas supplier configured to supply a titanium tetrachloride (TiCl₄) gas, which is a titanium compound. The TiCl₄ gas supplier includes a TiCl₄ gas source 64 and a supply path 65. A flow-rate adjuster M1 and a valve V1 are interposed and installed in the supply path 65 from the upstream side. Further, the gas supply mechanism 4 includes an H₂ gas supplier configured to supply a hydrogen (H₂) gas, which serves as a reducing gas, and an Ar gas supplier configured to supply an argon (Ar) gas, which serves as a gas for plasma generation.

The H₂ gas supplier includes an H₂ gas source 66 and a supply path 67. A flow-rate adjuster M2 and a valve V2 are interposed and installed in the supply path 67 from the upstream side. The Ar gas supplier includes an Ar gas source 68 and a supply path 69. A flow-rate adjuster M3 and a valve V3 are interposed and installed in the supply path 69 from the upstream side. The TiCl₄ gas, H₂ gas, and Ar gas, which serve as film formation gases, correspond to process gases used in the substrate processing apparatus.

Further, an annular lid 12 is installed on an upper surface of the processing container 3. An annular seal member 13 is installed in an inner peripheral portion of the annular lid 12. The support portion 9f of the middle plate 9b, which is installed in an inner peripheral portion of the seal member 13, is supported by the annular lid 12 via the seal member 13. An outer portion of the flange 9fa in the support portion 9f of the middle plate 9b is covered by an annular insulating member 14, and the annular insulating member 14 is also supported by the annular lid 12.

In this way, the flange 9fa of the support portion 9f of the middle plate 9b is supported by the insulating member 14 and the seal member 13 while being sandwiched between the insulating member 14 and the seal member 13, and the shower head 9 is supported by the annular lid 12 via the insulating member 14 and the seal member 13. Further, the insulating member 14 and the seal member 13 may be made of ceramics such as Al₂O₃, in order to electrically insulate and thermally isolate the shower head 9, to which radio frequency power is applied, from the annular lid 12 and the processing container 3.

An annular filler 70 is fitted into a space enclosed by the outer surfaces of the lower plate 9a and the middle plate 9b, which form a lower portion of the shower head 9, a lower surface of the seal member 13, a lower surface and an inner surface of the annular lid 12, and the sidewall of the processing container 3. The filler 70 is made of, for example, quartz, and serves to prevent plasma generation in the space into which the filler 70 is fitted. The filler 70 includes a ring-shaped second heater 70a, which surrounds an exterior of the lower plate 9a. The second heater 70a prevents by-products caused by the film formation gases from adhering onto the filler 70 and the surroundings of the filler 70, and also adjusts the shower head 9 to a target temperature in cooperation with the first heater 9j. The first heater 9j and the second heater 70a constitute a heating mechanism of the shower head 9. However, providing the second heater 70a may not be necessary, and the shower head 9 may also be heated using only the first heater 9j.

In the above configuration, to maintain airtightness between the respective components, resin seal rings 15 such as O-rings are interposed respectively between the processing container 3 and the annular lid 12, between the annular lid 12 and the seal member 13, and between the seal member 13 and the flange 9fa of the support portion 9f of the middle plate 9b. Among these seal rings 15, a seal ring 15a installed between the seal member 13 and the flange 9fa requires temperature adjustment because it is in contact with the flange 9fa, which is heated to a high temperature by the heating mechanism.

Therefore, the film forming apparatus 1 of this example includes a cooling device 2 for cooling members (hereinafter, also referred to as “cooling target TC”) arranged around the seal ring 15a. The cooling device 2 cools the cooling target TC arranged around the seal ring 15a, thereby adjusting the temperature of the seal ring 15a to be equal to or less than a heat resistant temperature of the seal ring 15a. The cooling device 2 of this example performs air cooling of the cooling target TC such as the annular flange 9fa, the lid 10 disposed on the flange 9fa, and the insulating member 14.

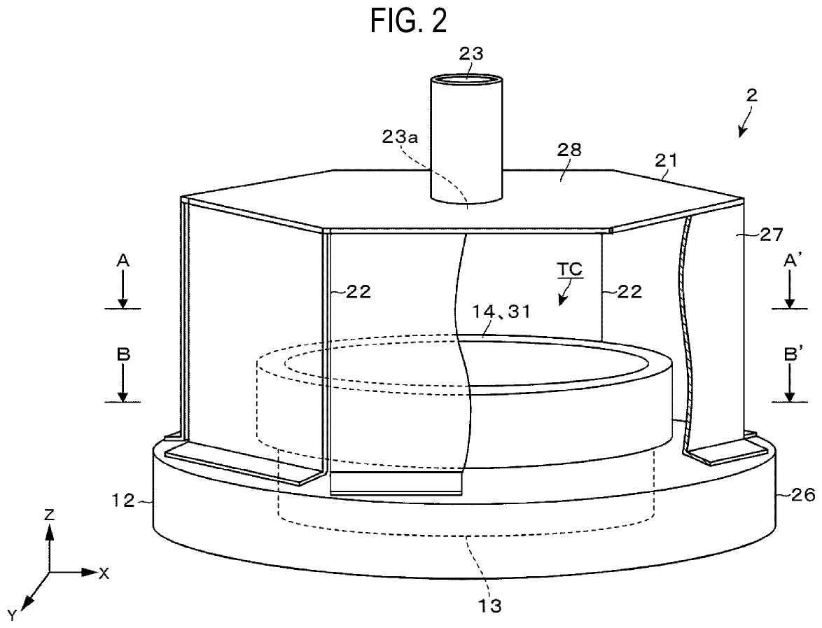

FIG. 2 is a perspective view illustrating the cooling device according to the present disclosure.

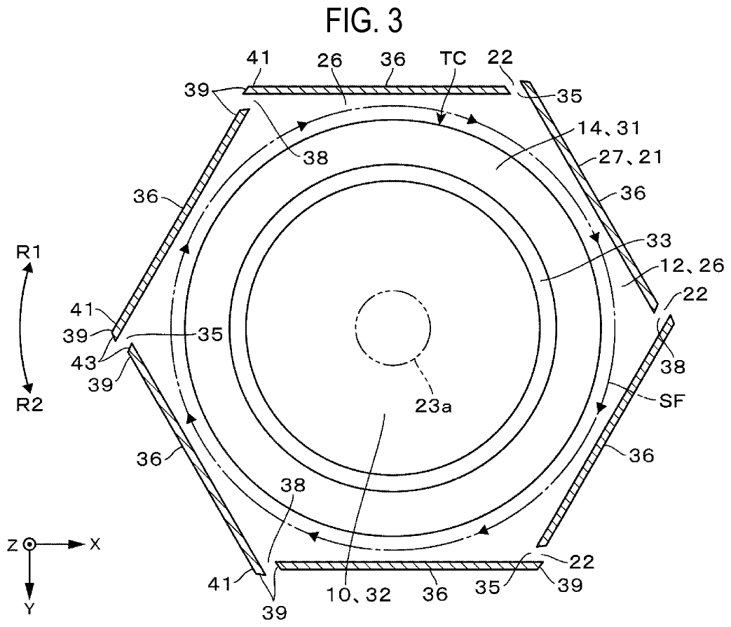

FIG. 3 is a cross-sectional plan view of the cooling device according to the present disclosure. FIG. 3 is a cross-sectional plan view taken along line A-A′ illustrated in FIG. 2, viewed in the arrow direction.

The cooling device 2 includes a housing 21 for accommodating the cooling target TC, a plurality of supply holes 22 for allowing external air to enter the housing 21 from an external space of the housing 21, and a discharge path 23 for discharging a gas inside the housing 21. The housing 21 includes a bottom wall 26 in which the cooling target TC is disposed, a sidewall 27 installed in an outer peripheral region of the bottom wall 26 to surround the cooling target TC, and a ceiling wall 28 installed on an upper surface of the sidewall 27.

The sidewall 27 is formed as a substantially annular body, specifically in a hexagonal prism shape, and includes openings in a top surface and a bottom surface. The bottom wall 26 is installed below the bottom surface of the sidewall 27 and blocks a lower opening of the sidewall 27. As illustrated in FIG. 1, the bottom wall 26 includes the above-described annular lid 12, the seal member 13, the insulating member 14, the upper portion of the shower head 9, and lid 10 in the film forming apparatus 1. In other words, the bottom wall 26 corresponds to a portion exposed on an upper surface of the film forming apparatus 1 when the sidewall 27 or the ceiling wall 28 of the housing 21 is removed.

Due to the structure of the upper surface side of the film forming apparatus 1 as described above with reference to FIG. 1, the cooling target TC disposed on the bottom wall 26 has irregularities. Specifically, the cooling target TC includes an annular protruding wall portion 31, which protrudes from the bottom wall 26 toward the ceiling wall 28 and extends annularly along the sidewall 27 when viewed in a plan view, a central bottom portion 32 provided inside the annular protruding wall portion 31, and an annular groove 33 formed between the central bottom portion 32 and the annular protruding wall portion 31.

The annular protruding wall portion 31 is formed by the previously described insulating member 14, which is provided to protrude upward from the annular lid 12 forming the outer periphery of the bottom wall 26.

Further, the central bottom portion 32 is formed by the lid 10, which covers the recess of the middle plate 9b, and the upper surface of the lid 10 is positioned higher than the upper surface of the annular lid 12, which is located on the outer periphery. The annular groove 33 is a gap between the insulating member 14 and the lid 10. The bottom surface of the annular groove 33 is formed by the upper surface of the flange 9fa of the shower head 9. The lid 10 and the insulating member 14 are spaced apart from each other on the upper surface of the flange 9fa of the shower head 9 to form the annular groove 33, so that the flange 9fa of the shower head 9 is exposed inside the housing 21. Thus, the flange 9fa of the shower head 9 is directly cooled by a gas inside the housing 21.

The ceiling wall 28 is attached to the upper end of the sidewall 27 to block the opening in the top surface of the sidewall 27, and is arranged to face the cooling target TC. The ceiling wall 28 of this example has a regular hexagonal shape in a plan view and has a central portion connected to a downstream end of the discharge path 23, which opens toward the interior of the housing 21.

As illustrated by the two-dot dashed line in FIG. 3, an opening 23a of the discharge path 23 is positioned at a center portion of a region surrounded by the sidewall 27, when the housing 21 is viewed in a plan view. In other words, the opening 23a of the discharge path 23 is positioned to face a center portion of the cooling target TC. The opening 23a of the discharge path 23 opens downward toward the cooling target TC. The discharge path 23 is connected to an exhaust system for a factory utility where the film forming apparatus 1 is installed. By suctioning and discharging a gas inside the housing 21 from the opening 23a through the exhaust system, external air may be introduced into the housing 21 through the plurality of supply holes 22.

The plurality of supply holes 22 are arranged on the sidewall 27 at intervals from each other and are each formed to penetrate the sidewall 27. Each supply hole 22 forms a flow path for allowing external air to enter the housing 21 and guides the external air to release it in a preset direction inside the housing 21. As illustrated in FIG. 3, the external airflow released from each supply hole 22 imparts kinetic energy to a gas inside the housing 21 to cause the gas inside the housing 21 to rotate in the clockwise direction (hereinafter referred to as “rotation direction R1”) when viewed in a plan view, forming a swirling flow SF along with the gas inside the housing 21. In addition, FIG. 3 also indicates the counterclockwise direction (hereinafter referred to as “counter-rotation direction R2”) when viewed in a plan view.

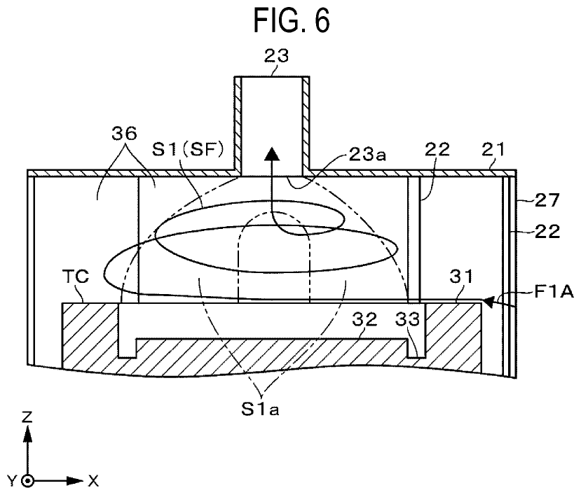

Referring to the outline of the swirling flow SF as indicated by the one-dot dashed line in FIG. 3, the swirling flow SF rotates in a preset rotation direction (clockwise rotation direction R1 in the example of FIG. 3) along the inner surface of the sidewall 27. More specifically, the swirling flow SF flows to rotate around the opening 23a of the discharge path 23 when viewed in a plan view, forming a vortex flow directed toward the opening 23a of the discharge path 23. Further, as illustrated in FIG. 6, the swirling flow SF becomes an upward swirling flow to flow from the bottom wall 26 toward the opening 23a of the discharge path 23.

Therefore, the cooling device 2 of the present disclosure may form a desired swirling flow SF by appropriately setting a planar shape of the housing 21 (the orientation of the sidewall 27), a length of each supply hole 22, a direction in which external air is released from the supply hole 22 into the housing 21, and a position of the opening 23a of the discharge path 23. Here, the direction in which external air is released from the supply hole 22 specifically refers to the orientation of the downstream end of a flow path formed by the supply hole 22, i.e., the orientation of a downstream opening 35 of an internal space of the supply hole 22, as illustrated in FIG. 3.

For the cooling device 2 illustrated in FIG. 3, for example, if the supply holes 22 are arranged in a mirror-symmetrical manner when viewed in a plan view using the above-described method, a swirling flow SF rotating in the counterclockwise counter-rotation direction R2 may be formed.

As illustrated in FIG. 3, the direction in which external air is released from each supply hole 22 is set to the direction along the swirling flow SF when viewed in a plan view, in order to form the swirling flow SF in the rotation direction R1. The direction along the swirling flow SF means that when external air released from each supply hole 22 merges with the swirling flow SF, the direction of a streamline component of external airflow that corresponds to the tangential direction of the swirling flow SF aligns with the flow direction of the swirling flow SF (rotation direction R1 in the example of FIG. 1). The alignment between the direction of external air released from each supply hole 22 and the flow direction of the swirling flow SF may be confirmed through fluid simulation, for example.

On the other hand, if the direction of a streamline component of external airflow that corresponds to the tangential direction of the swirling flow SF when the external air merges with the swirling flow SF is opposite to the flow direction of the swirling flow SF (counter-rotation direction R2 in the example of FIG. 3), the formation of the swirling flow SF will be hindered. Further, if the external airflow does not have a component corresponding to the tangential component of the swirling flow SF, the external air will flow only in the radial direction intersecting the rotation direction R1, which hinders the formation of the swirling flow SF.

Hereinafter, detailed configurations of the sidewall 27 and the supply holes 22 will be described. The sidewall 27 is configured as a substantially annular hexagonal prism as described above, so that the airflow generated inside the housing 21 may be guided along the inner surface of the sidewall 27, and the swirling flow SF that rotates along the inner surface may be formed. The sidewall 27 is composed of six wall members 36 arranged to surround the cooling target TC, and each of six rectangular side surfaces of the sidewall 27 is generally formed by a single plate-shaped wall member 36. These wall members 36 have the same shape, and surround the cooling target TC by the front and back surfaces thereof. In this way, the sidewall 27 is formed by arranging the six wall members 36 annularly around the cooling target TC.

Six supply holes 22 are arranged on the sidewall 27 at an equal angular interval around the opening 23a of the discharge path 23 when viewed in a plan view. Each supply hole 22 is formed in the sidewall 27 at a position (hereinafter referred to as “junction 38”) where end portions (side end portions 39 to be described later) of two adjacent wall members 36 adjoin. Six junctions 38 are set to portions that respectively include vertices 41 of the hexagonal sidewall 27 when viewed in a plan view. At each junction 38, the adjacent side end portions 39 of two wall members 36, which are arranged in the rotation direction R1, are spaced apart from each other and are positioned to be adjacent at an angle corresponding to, for example, the interior angle of a hexagon.

In addition, the term “equal angular interval” is not limited to the case where the supply holes 22 are arranged at an exact equal angular interval. For example, even if the supply holes 22 are shifted by approximately ±5° from an exact equal angular interval, the effect of uniformly introducing external air from different circumferential positions of the sidewall 27 may still be achieved, and such an arrangement falls within the concept of “equal angular interval” in the present disclosure. Each supply hole 22 is formed between the side end portions 39 of two wall members 36, which are spaced apart from each other at each junction 38, and is configured as a vertically elongated slit along the side end portions 39 of the respective wall members 36.

Here, when each junction 38 is viewed in a plan view, an end surface 43 of the side end portion 39 of one wall member 36 positioned upstream in the rotation direction R1 is arranged to face the side surface of the side end portion 39 (inner surface of the sidewall 27) of the other wall member 36 positioned downstream in the rotation direction R1. With this configuration, external air introduced from the external space is guided to the inner surface of the sidewall 27 on the rotation direction R1 of each supply hole 22, and is then released from each supply hole 22 to flow along the swirling flow SF. Further, with this configuration, each supply hole 22 is formed along the tangential direction of the sidewall 27 on the rotation direction R1 when viewed in a plan view, allowing external air to enter the housing 21 from each supply hole 22 along the tangential direction of the sidewall 27 located on the rotation direction R1 of each supply hole 22. The direction in which external air is released from each supply hole 22 as described above is set to align with the direction along the swirling flow SF when viewed in a plan view. The above-described structure may be easily achieved by offsetting each wall member 36 in the counter-rotation direction R2 along the sides of a hexagon from a state where two adjacent wall members 36 are in contact at the junction 38.

As described above, in the cooling device 2 of this example, the sidewall 27 is composed of a plurality of wall members 36 arranged in a substantially annular shape, with the supply holes 22 positioned at the respective vertices 41 of a hexagon. Then, by configuring each supply hole 22 to release external air along the inner surface of the sidewall 27, the external airflow along the swirling flow SF may be easily formed.

Further, the external air released from each supply hole 22 tends to flow toward the opening 23a of the discharge path 23 while forming the swirling flow SF. Therefore, for example, the trajectory to the opening 23a of the discharge path 23 becomes longer, compared to a flow that moves straight from each supply hole 22 to the opening 23a of the discharge path 23 without forming the swirling flow SF. The swirling flow SF comes into contact with the cooling target TC evenly throughout the entire region inside the housing 21, enabling efficient heat dissipation.

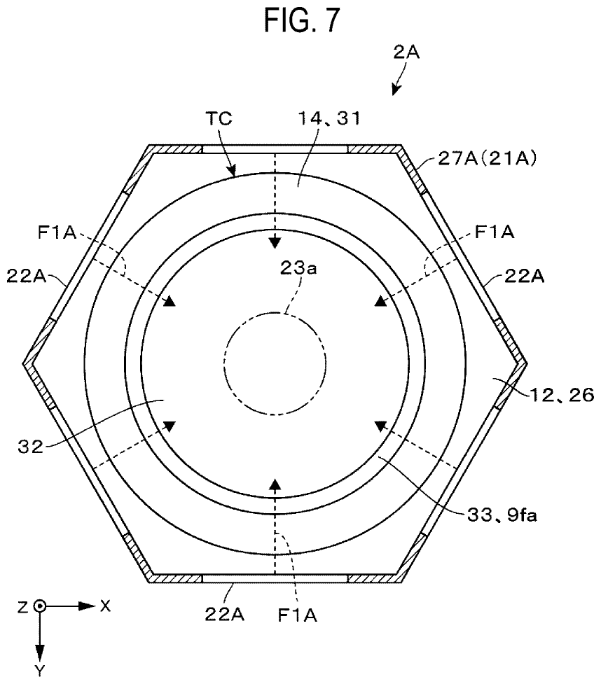

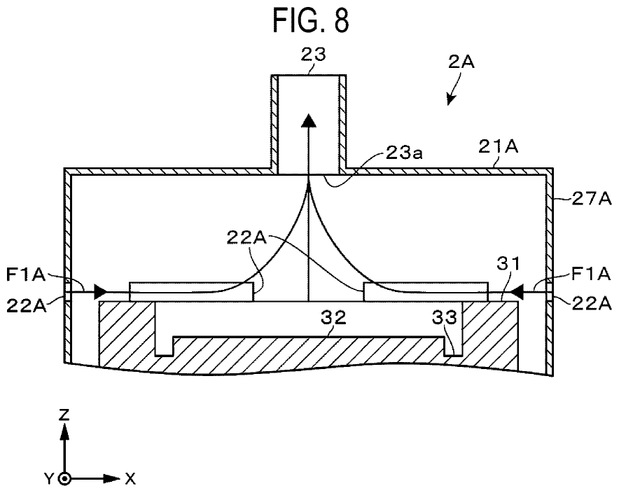

Further, as described above with reference to FIG. 1, the cooling target TC disposed on the bottom wall 26 of the cooling device 2 has irregularities (the annular protruding wall portion 31, the annular groove 33, and the central bottom portion 32) in the radial direction extending from the sidewall 27 toward the opening 23a of the discharge path 23. In this case, as illustrated in FIGS. 7 and 8 to be described later, if external airflow moving straight from each supply hole 22 to the opening 23a of the discharge path 23 is formed inside the housing 21, it is difficult for the external airflow to sufficiently penetrate the irregularities, resulting in poor cooling efficiency. Further, since the flow moving straight to the opening 23a of the discharge path 23 flows in a direction intersecting the irregularities, the flow becomes turbulent due to the contact with the irregularities. This turbulence increases pressure loss, making it even more difficult for the airflow to penetrate the irregularities and to effectively cool the cooling target TC.

In this regard, the swirling flow SF flows from each supply hole 22 to the opening 23a of the discharge path 23, while also flowing circumferentially along the annular and circular contours of the annular protruding wall portion 31, the annular groove 33, and the central bottom portion 32, which constitute the irregularities of the cooling target TC. Therefore, turbulence of the swirling flow SF may be prevented, allowing for the formation of stable and fast airflow.

The film forming apparatus 1, which includes the cooling device 2 having the above-described configuration, is provided with the controller 100 as illustrated in FIG. 1. The controller 100 is configured by, for example, a computer, and includes a program, a memory, and a data processing unit including a CPU.

The program contains commands that allow the controller 100 to send control signals to various components of the film forming apparatus 1 and proceed with each step related to film formation (film formation step). The program is stored in a non-transitory computer storage medium such as a flexible disk, compact disk, hard disk, magneto-optical (MO) disk, or non-volatile memory, and is installed in the controller 100. The controller 100 controls and operates various components of the film forming apparatus 1 described above according to operator inputs and preset programs.

Hereinafter, the operation of the cooling device 2 according to the present embodiment will be described.

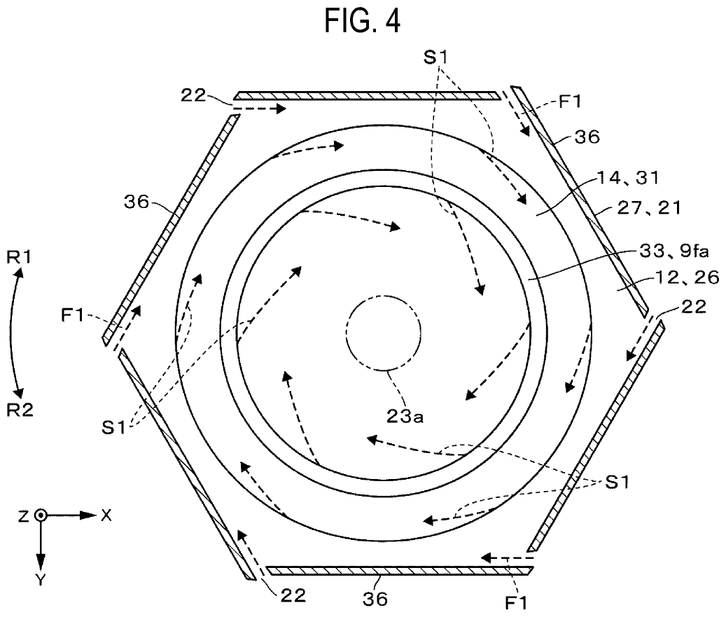

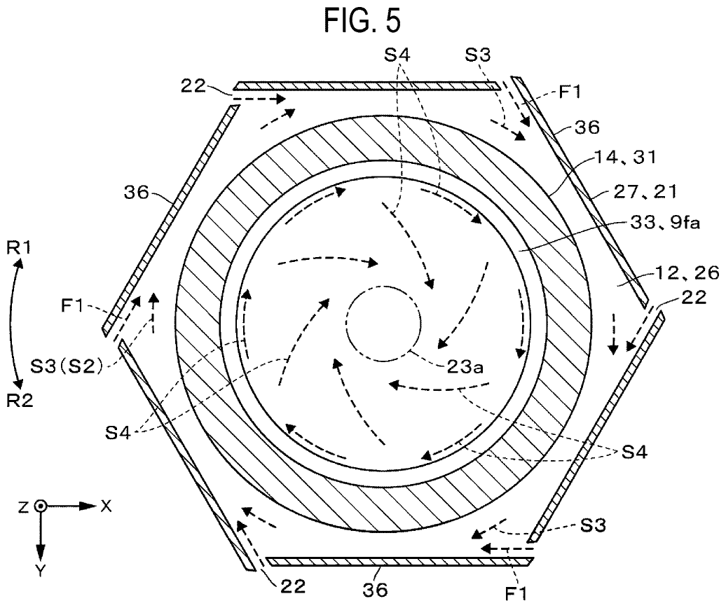

FIGS. 4 and 5 are cross-sectional plan views illustrating an operation of the cooling device according to the present disclosure.

FIG. 4 is a top cross-sectional view taken along line B-B′ in FIG. 2 as viewed in the arrow direction, and FIG. 5 is a bottom cross-sectional view taken along line A-A′ in FIG. 2 as viewed in the arrow direction. In FIGS. 4 and 5, the airflow streamlines are partially indicated by dashed arrows, with the lengths of the dashed arrows indicating airflow velocities.

As illustrated in FIGS. 4 and 5, by the suction of the discharge path 23, external airflow F1 enters the housing 21 from each of the six supply holes 22, which are arranged at an equal angular interval around the opening 23a of the discharge path 23 when viewed in a plan view. Therefore, the external airflow F1 enters the housing 21 uniformly from the surrounding external space when viewed in a plan view, ensuring uniform cooling inside the housing 21. As described above, each supply hole 22 is configured as a vertically elongated slit along the side end portion 39 of the wall member 36. Therefore, the external airflow F1 enters substantially uniformly along the height direction of each supply hole 22. Accordingly, as illustrated in the example of FIGS. 1 and 2, the external airflow F1, immediately after entering, enables cooling of the cooling target TC, not only for the cooling target TC located close to the bottom wall 26 of the cooling device 2 but also the cooling target TC located at a higher position inside the housing 21, such as the upper portion of the annular protruding wall portion 31, in the same manner as at a lower position inside the housing 21.

In the entire region inside the housing 21, as described above, the external airflow F1 from each supply hole 22 is released along the inner surface of the sidewall 27 on the rotation direction R1 side, imparting kinetic energy to a gas inside the housing 21 to cause the air to rotate in the rotation direction R1 of the swirling flow SF. Then, the external airflow F1 released from each supply hole 22 forms the swirling flow SF along with the gas inside the housing 21. The upward swirling flow SF formed in this way rotates along the inner surface of the sidewall 27 while simultaneously rising from the bottom wall 26 toward the opening 23a of the discharge path 23. Since the internal space of the housing 21 has different spatial characteristics in certain regions, a detailed operation of the swirling flow SF will be described below, categorized into an upper swirling flow S1 in the upper region of the housing 21 and a lower swirling flow S2 in the lower region of the housing 21.

FIG. 6 is a longitudinal cross-sectional side view illustrating an operation of the cooling device according to the present disclosure. FIG. 6 exemplifies a flow of single external airflow F1 toward the discharge path 23, and illustrates a schematic representation of the upper swirling flow S1 inside the housing 21.

As illustrated in FIGS. 4 and 6, there is no structure that interferes with airflow, such as the annular protruding wall portion 31 of the bottom wall 26, inside the upper region of the housing 21. The airflow of the upper swirling flow S1 in the upper region of the housing 21 tilts toward the opening 23a of the discharge path 23 when viewed in a plan view and increases in flow velocity as it approaches the opening 23a of the discharge path 23. Further, although not illustrated in FIGS. 4 and 6, the airflow of the upper swirling flow S1 tilts upward as it approaches the opening 23a of the discharge path 23. Here, referring to the schematic range of the swirling flow S1 as indicated by the two-dot dashed line in FIG. 6, the swirling of the airflow of the upper swirling flow S1 become stronger inside, specifically, at an inner strong swirling flow Sla that expands downward from the opening 23a of the discharge path 23. Furthermore, the swirling becomes weaker in a region inside the inner strong swirling flow Sla. Such a velocity distribution has been confirmed by fluid simulation.

As illustrated in FIG. 5, there is a structure that interferes with airflow, such as the annular protruding wall portion 31 of the bottom wall 26, in the lower region inside the housing 21. Therefore, the lower swirling flow S2 inside the lower region of the housing 21 will be described below, categorized into an outer swirling flow S3 outside the annular protruding wall portion 31 and an inner swirling flow S4 inside the annular protruding wall portion 31. The outer swirling flow S3 is formed when the external airflow F1 released from each supply hole 22 directly merges. The outer swirling flow S3 swirls upward in the gap between the inner surface of the sidewall 27 and the outer wall surface of the annular protruding wall portion 31.

The gap between the inner surface of the sidewall 27 and the outer wall surface of the annular protruding wall portion 31 is narrower than locations where other swirling flows S1 and S4 flow, and particularly when viewed in a plan view, becomes even narrower in the region where the inner surface center of each wall member 36 faces the outer wall surface of the annular protruding wall portion 31, resulting in increased pressure loss. The average flow velocity of the outer swirling flow S3 tends to decrease compared to the flow velocity of the external airflow F1. However, compared to the case where airflow moves straight from the supply hole 22 to the opening 23a of the discharge path 23 as illustrated in FIGS. 7 and 8 to be described later, the outer swirling flow S3 is formed even at a lower velocity to flow along the lower region outside the annular protruding wall portion 31, thereby effectively cooling that region.

On the other hand, a gas inside the annular protruding wall portion 31 may have difficulty in directly merging with the external airflow F1. However, as illustrated in FIG. 6, the inner strong swirling flow Sla of the upper swirling flow S1, formed above the annular protruding wall portion 31, pulls the gas inside the annular protruding wall portion 31 to cause it to swirl upward, forming the inner swirling flow S4. The inner swirling flow S4 swirls strongly in the region below the inner strong swirling flow Sla, specifically in the region inside the annular protruding wall portion 31, except for the region directly below the opening 23a of the discharge path 23.

With the cooling device 2 that generates the swirling flow SF throughout the entire region inside the housing 21, the entire surface of the cooling target TC positioned in the bottom wall 26 inside the housing 21 may be effectively cooled using a gas of the external space. In particular, even if the cooling target TC has an uneven structure as in the present embodiment, the upper surface of the annular protruding wall portion 31 may be cooled by the upper swirling flow S1, the outer wall surface of the annular protruding wall portion 31 may be cooled by the outer swirling flow S3, and the inner wall surface of the annular protruding wall portion 31 and annular groove 33 may be cooled by the inner swirling flow S4. Further, the central bottom portion 32 may be cooled by the inner swirling flow S4.

In this way, the cooling device 2 of this example may effectively cool the cooling target TC using the swirling flow SF, which is formed by the external airflow F1 introduced from the plurality of supply holes 22. In the film forming apparatus 1, the cooling device 2 may cool the shower head 9 from above, and may adjust the temperature of a member arranged around the seal ring 15a to be equal to or less than the heat resistant temperature of the seal ring 15a. Further, by utilizing the gas introduced from the external space of the housing 21, the consumption of factory utility may be reduced, for example, compared to a case where clean air supplied for the factory utility is directly blown onto the cooling target TC for cooling.

Hereinafter, for comparison with the cooling device of the present disclosure, the cooling device 2 that has a comparative supply hole 22A of a different shape from the supply hole 22 in the present embodiment and an operation thereof will be described.

FIG. 7 is a cross-sectional plan view illustrating the operation of a cooling device according to a comparative embodiment.

FIG. 8 is a longitudinal cross-sectional side view illustrating the operation of the cooling device according to the comparative embodiment.

Six supply holes 22A in the comparative embodiment are horizontally notched in the center of six rectangular wall portions of a hexagonal prism-shaped sidewall 27A. In addition, the opening area of each supply hole 22A is approximately the same as the opening area of the supply hole 22 in the present embodiment. When viewed in a plan view, a plurality of supply holes 22A each releases external airflow F1A toward the center of the internal space of a housing 21A, i.e., toward the opening 23a of the discharge path 23, so that the airflow moves straight toward the opening 23a of the discharge path 23 without forming the swirling flow SF.

As illustrated in FIG. 7, the plurality of supply holes 22A is positioned to cause the external airflow F1A to flow in a vicinity of the upper surface of the annular protruding wall portion 31 for cooling the annular protruding wall portion 31. While the external airflow FIA flows directly over the upper surface of the annular protruding wall portion 31 to effectively cool the upper surface of the annular protruding wall portion 31, it is directed upward as it approaches the opening 23a of the discharge path 23, and thus, it is difficult to cool the region inside the annular protruding wall portion 31. The trajectory of the external airflow F1A in the comparative embodiment is shorter and more localized compared to the trajectory of the swirling flow SF formed by the external outflow F1 in the present embodiment, leading to uneven cooling inside the housing 21A. Thus, the cooling device 2 of the present disclosure may cool more effectively than the cooling device 2A of the comparative embodiment.

The discharge path 23 of the cooling device 2 in the present embodiment is connected to the exhaust system for the factory utility, but the method of applying a negative pressure inside the housing 21 is not limited to this. For example, a fan or other components may be attached to the discharge path 23.

In the film forming apparatus 1 which is one example of the present disclosure, the film formation gases may include a precursor gas containing a film precursor, a reducing gas, and a gas for plasma generation, but are not limited thereto. The present disclosure may also be applied to a thermal decomposition CVD film forming apparatus using only a precursor gas containing a film precursor, or an ALD film forming apparatus using both a precursor gas and a reactant gas.

The substrate processing of the substrate processing apparatus according to the present disclosure is not limited to film formation but may include etching, ashing to remove a resist film using oxygen plasma, and annealing to heat a substrate under a gas supply atmosphere such as an inert gas atmosphere. For such processes, a shower head releases process gases suited to various processes from a gas supply mechanism into a processing container to perform various processes on a substrate, and a cooling device may cool a cooling target that increases in temperature by the heating of a constituent member of the shower head.

Further, the sidewall 27 in the present embodiment is not limited to a hexagonal prism shape, but may also be a polygonal prism shape, a cylinder shape, or a dome shape where the ceiling wall 28 and the sidewall 27 are integrated. The cooling target TC in the present embodiment is integrated with the bottom wall 26, but is not limited to this, and may be simply placed on the bottom wall 26, or may be positioned elsewhere inside the housing 21 other than the bottom wall 26. Further, it is desirable to provide the annular groove 33 in the present embodiment, but the annular groove 33 may not be formed, and the lid 10 and the insulating member 14 may be in contact with each other. If the film forming apparatus does not use plasma, the insulating member 14 and seal member 13 may be formed of aluminum, a resin material, or other materials.

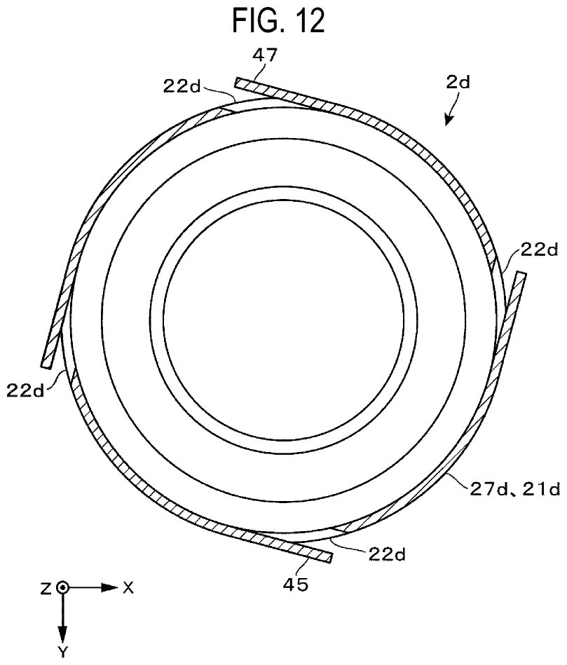

Further, the supply hole 22 in the present embodiment is not limited to being formed in the junction 38 of the sidewall 27, i.e., between two adjacent wall members 36, but may be formed, for example, within the plane of the wall member 36. Even when the supply hole 22 is formed within the plane of each wall member 36, the supply hole 22 may be positioned to release the external airflow along the swirling flow SF under an assumption that the swirling flow SF is formed inside the housing 21. In addition, the formation of the supply hole 22 within the plane of the wall member 36 is not limited to the case where the housing 21 is formed in a polygonal shape in a plan view as illustrated in FIG. 3. It is also possible to form the swirling flow SF by forming the supply hole 22 within the plane of the wall member 36 of the housing 21 formed in a circular shape when viewed in a plan view, as illustrated in FIG. 12 to be described later.

### Second Embodiment

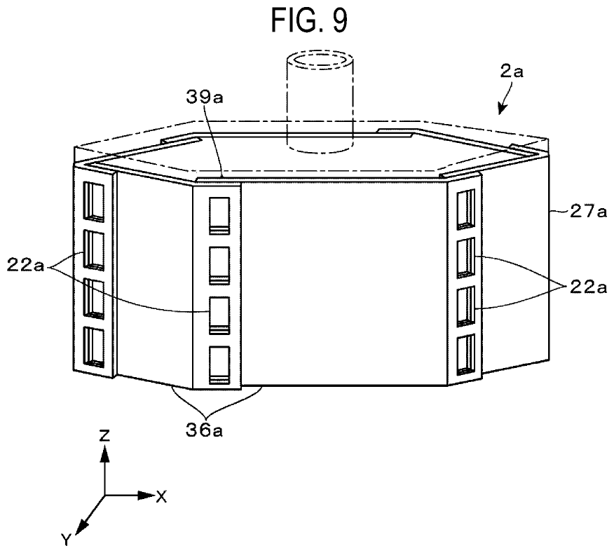

As a second embodiment of the substrate processing apparatus according to the present disclosure, a cooling device 2a having a supply hole 22a notched in a sidewall 27a will be described. As illustrated in FIG. 9, compared to the cooling device 2 having the vertically elongated slit-shaped supply hole 22 as described above with reference to FIG. 2 and other drawings, the cooling device 2a has a different supply hole configuration in which a plurality of supply holes 22a, configured as small rectangular or circular holes (rectangular in the example illustrated in FIG. 9), are arranged vertically along a side end portion 39a of each wall member 36a.

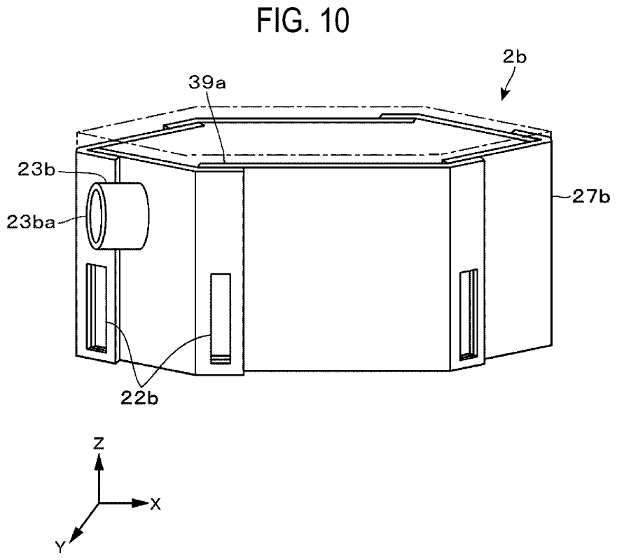

Further, in the example of a cooling device 2b illustrated in FIG. 10, an opening 23ba of a discharge path 23b is provided on the sidewall 27b. The opening 23ba is located higher than a supply hole 22b. Thus, an upward swirling flow may be formed, similar to the first embodiment.

The plurality of supply holes 22a or 22b in the present embodiment and the supply holes 22 in the first embodiment disclosed above allow adjustment of the entering locations of external air by partially blocking some of the supply holes. Specifically, the entering locations of external air may be appropriately adjusted by blocking a partial region of the vertically extending supply hole 22 or 22b or by blocking some of the plurality of supply holes 22a arranged in the vertical direction. Thus, cooling may be appropriately adjusted based on the placement of the cooling target TC or a desired cooling level.

### Third Embodiment

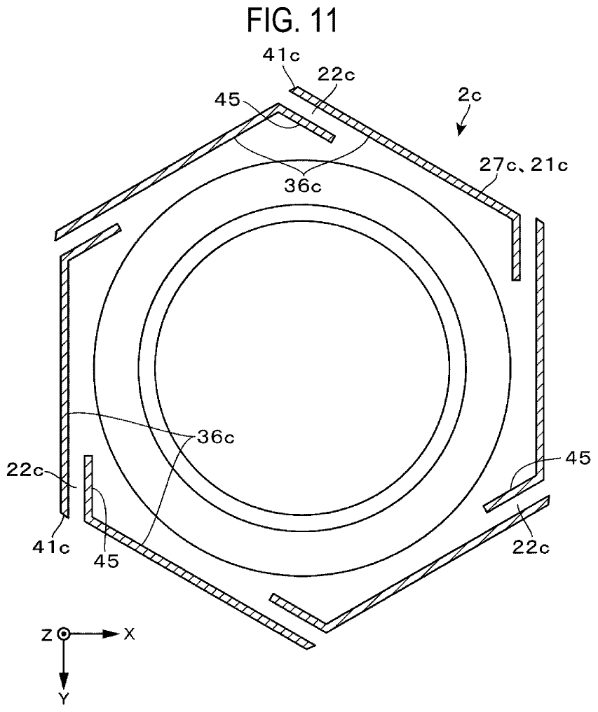

Next, a cooling device 2c illustrated in FIG. 11 includes a supply hole 22c configured as a flow path to extend between the external space and the interior of the housing. The supply hole 22c in this example is formed by an inner surface of a wall member 36c constituting a sidewall 27c and a flow path wall member 45 arranged to face the inner surface. In particular, in the example illustrated in FIG. 11, the wall member 36c constituting the sidewall 27c is pushed inward of a housing 21c from a position corresponding to a vertex 41c of the hexagonal sidewall 27c, forming the flow path wall member 45. Thus, the supply hole 22c may be configured as a flow path having a longer length than the supply hole 22 illustrated in FIG. 2. Such a supply hole 22c may laminarize the external air passing therethrough, thereby enabling the formation of a stronger swirling flow SF.

In addition, the method of forming the supply hole 22c as a flow path extending between the external space and the interior of the housing 21c is not limited to the example illustrated in FIG. 11. For example, two flow path wall members 45, arranged at intervals, may be inserted from a position corresponding to the vertex 41c or the center of the sidewall 27c, and the tips of the two flow path wall members 45 may be oriented to release external air in the direction along the swirling flow SF.

### Fourth Embodiment

As illustrated in FIG. 12, a cooling device 2d according to a fourth embodiment of the substrate processing apparatus of the present disclosure includes a supply hole 22d, which is notched in a cylindrical sidewall 27d and has a guide plate 47 for guiding external air to be released in the direction along the swirling flow SF.

In addition, the embodiments disclosed herein should be considered to be exemplary and not limitative in all respects. The above embodiments may be omitted, replaced, modified, or combined in various ways without departing from the scope and spirit of the appended claims.

### EXAMPLES

### (Simulation 1)

The formation of the swirling flow SF inside the housing 21 by the cooling device 2 of this example was confirmed through fluid simulation.

### A. Simulation Condition

### Example 1

A simulation model was formed based on the cooling device 2 having a configuration described above with reference to FIGS. 2 and 3, and the flow of a gas inside the housing 21 was visualized.

### B. Simulation Results

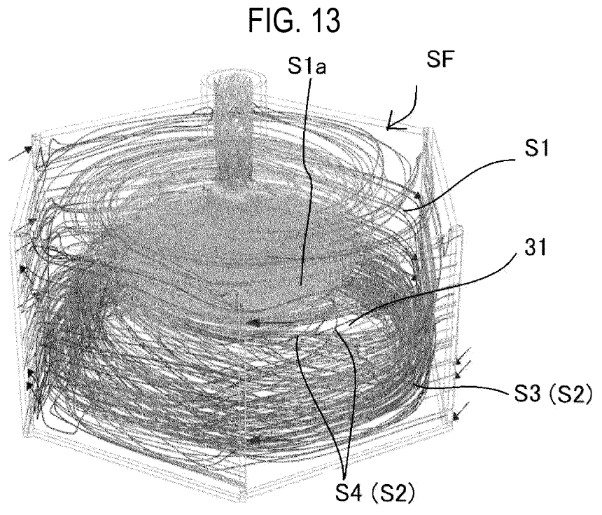

The simulation results are illustrated in FIG. 13. As indicated by streamlines in FIG. 13, it could be confirmed that a flow corresponding to the swirling flow SF, described above with reference to FIGS. 4 to 6, was formed inside the housing 21.

### (Simulation 2)

A simulation was conducted to evaluate how the state of a flow formed inside the housing 21 affects the cooling of the cooling target TC.

### A. Simulation Condition

### Example 2

In the simulation model corresponding to Example 1, the temperature distribution of a gas inside the housing 21 was obtained. Further, thermal simulation was performed to analyze the temperature distribution of the cooling target TC. When cooling was not applied, the average temperature of the cooling target TC was approximately 350 degrees C., the gas temperature was set to 20 degrees C., and the discharge flow rate from the discharge path 23 was set to 1 Nm³/min.

### Comparative Example 2

A simulation model was formed for the cooling device 2A according to the comparative embodiment, which was described with reference to FIGS. 7 and 8, and the same simulation as in Example 2 was conducted.

### B. Simulation Results

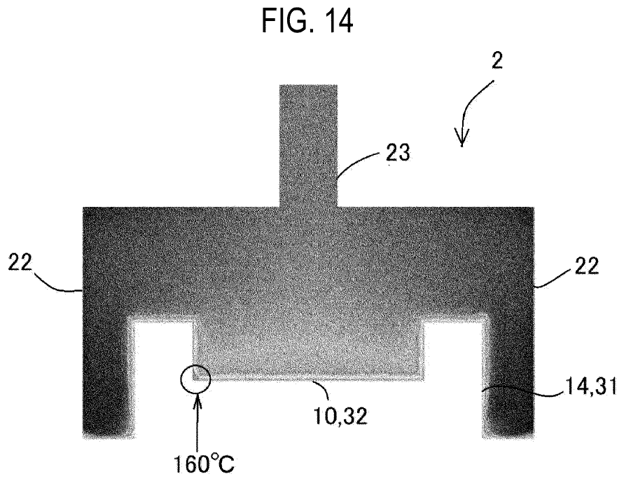

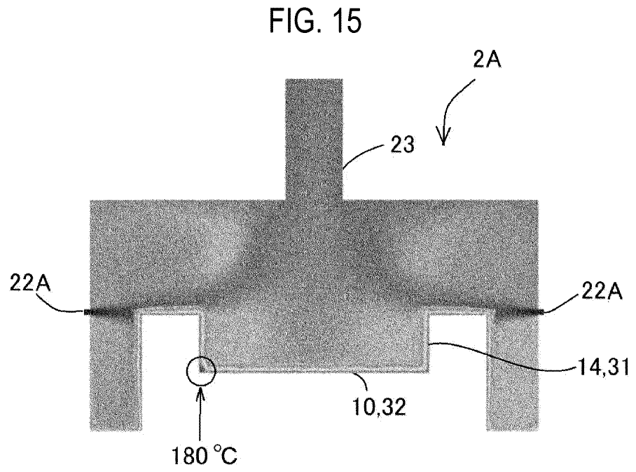

The temperature distributions of the gas inside the housing 21 for Example 2 and Comparative Example 2 are illustrated in FIGS. 14 and 15. According to the simulation results for Example 2 illustrated in FIG. 14, the temperature inside the housing 21 was lowered across the entire internal space, including both the lower outer region (outside the annular protruding wall portion 31) and the upper outer region inside the housing 21. The temperature of the gas at the lower end of the inner peripheral surface of the annular protruding wall portion 31, which is the most difficult to cool in the cooling target TC, was approximately 160 degrees C., and the average temperature of the cooling target TC was cooled to 178 degrees C.

On the other hand, according to the simulation results for Comparative Example 2, the temperature inside the housing 21A was generally higher throughout the internal space, except for regions where external airflow flows. The temperature of the gas at the lower end of the inner peripheral surface of the annular protruding wall portion 31 was approximately 180 degrees C., and the average temperature of the cooling target TC was 198 degrees C.

It could be confirmed from these simulation results that the cooling device 2 of the embodiment, which forms the swirling flow SF inside the housing 21, is more efficient in cooling the cooling target TC compared to the cooling device 2A of the comparative embodiment.

According to the present disclosure, it is possible to effectively cool a cooling target using a gas in the external space of a housing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cooling device that cools a cooling target using a gas, comprising:
a housing configured to accommodate the cooling target and having a sidewall surrounding the cooling target;
a plurality of supply holes arranged at an interval in the sidewall of the housing and serving as a flow path to introduce the gas from an external space of the housing to an interior of the housing; and
a discharge path opened to the housing and configured to discharge the gas in the interior of the housing,
wherein, to form a swirling flow rotating along the sidewall in the interior of the housing, each of the plurality of supply holes is formed toward a direction in which the gas is released along the swirling flow, when the housing is viewed in a plan view.

2. The cooling device of claim 1, wherein each of the plurality of supply holes is formed toward a direction in which the gas is released along an inner surface of the sidewall.

3. The cooling device of claim 1, wherein the housing includes a ceiling wall, which is arranged to face the cooling target, is configured to block an opening of the sidewall, and includes an opening of the discharge path, and
wherein the gas introduced from the plurality of supply holes forms the swirling flow that flows toward the opening of the discharge path while swirling.

4. The cooling device of claim 3, wherein the housing includes a bottom wall on which the cooling target is disposed, and
wherein the cooling target includes an annular protruding wall portion protruding from the bottom wall toward the ceiling wall and extending in an annular shape along the sidewall when viewed in the plan view.

5. The cooling device of claim 1, wherein an opening of the discharge path is located at a center portion of a region enclosed by the sidewall when the housing is viewed in the plan view, and
wherein, in the plan view, the plurality of supply holes is arranged at an equal angular interval around the opening.

6. The cooling device of claim 1, wherein the sidewall of the housing is formed by arranging a plurality of plate-shaped wall members in a direction surrounding the cooling target, and
wherein at least one of the plurality of supply holes is formed at a position where end portions of two of the adjacent wall members adjoin.

7. The cooling device of claim 1, wherein at least one of the plurality of supply holes is configured as the flow path and extends between the external space and the interior of the housing.

8. The cooling device of claim 7, wherein the extended supply hole is formed by an inner surface of a wall member forming the sidewall and a flow path wall member arranged to face the inner surface.

9. The cooling device of claim 1, wherein the plurality of supply holes is formed along an inner surface of the sidewall.

10. A substrate processing apparatus comprising:
a processing container configured to accommodate a substrate;
a shower head installed on an upper surface of the processing container to supply a process gas for processing the substrate toward an interior of the processing container, the shower head including a heating mechanism configured to heat a constituent member of the shower head; and
a gas supply mechanism configured to supply the process gas to the shower head,
wherein a cooling target that increases in temperature through heating of the constituent member of the shower head by the heating mechanism is disposed on an upper surface of the shower head, and
wherein the cooling device of claim 1 is installed to cover the cooling target of the shower head with the housing.

11. The substrate processing apparatus of claim 10, wherein the process gas is a film formation gas to form a film on the substrate.

12. A method of cooling a cooling target using a gas,
wherein a housing accommodating the cooling target includes a discharge path opened to the housing, a sidewall surrounding the cooling target, and a plurality of supply holes arranged at an interval in the sidewall,
wherein, to form a swirling flow rotating along the sidewall in an interior of the housing, each of the plurality of supply holes is formed toward a direction in which the gas is released along the swirling flow when the housing is viewed in a plan view, and
wherein the method comprises:
introducing the gas from an external space of the housing to release the gas to the interior of the housing through the plurality of supply holes to form the swirling flow;
cooling the cooling target by the swirling flow; and
discharging the gas from the discharge path.
